(19) United States
(12) Patent Application Publication
(10) Pub. No.: US 2025/0053085 A1
(43) Pub. Date: Feb. 13, 2025

(54) ORGANOTIN PHOTORESIST COMPOSITION AND METHOD OF STABILIZATION

(71) Applicant: Feng Lu, Irvine, CA (US)

(72) Inventor: Feng Lu, Irvine, CA (US)

(21) Appl. No.: 18/786,489

(22) Filed: Jul. 27, 2024

Related U.S. Application Data
(60) Provisional application No. 63/532,373, filed on Aug. 12, 2023.

(51) Int. Cl. G03F 7/004

(52) U.S. Cl. CPC G03F 7/0042; G03F 7/0045

(57) ABSTRACT

An organotin photoresist composition and a method of stabilization are described. The organotin photoresist composition comprises a (stannocenyl)tin compound, a solvent, and an additive. Stannocenyl includes bis(cyclopentadienyl)tin, or substituted bis(cyclopentadienyl)tin, wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group. A method of stabilization comprises the usage of organic molecules as additives to stabilize (stannocenyl)tin compound photoresists.

### CROSS REFERENCE TO RELATED APPLICATIONS

This application claims priority to U.S. provisional patent application No. 63/532,373 filed on Aug. 12, 2023 to Lu, entitled “Organotin photoresist composition and method of stabilization”, of which is entirely incorporated herein by reference.

### FIELD OF INVENTION

The present invention relates to organotin photoresist composition for actinic radiation and a method of stabilization, wherein organotin photoresist composition comprises a (stannocenyl)tin compound, a solvent, and an additive. The method of stabilization comprises applying organic molecules as additive to stabilize (stannocenyl)tin compound photoresists. Stannocenyl includes organometallic bis(cyclopentadienyl)tin, or substituted bis(cyclopentadienyl)tin.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light adsorption because metals have high adsorption capacity of ultraviolet radiation with various carbon-metal (C-M) bond dissociation energy (BDE), and then can be used as photoresists and/or the precursors for photolithography at smaller level (e.g., <7 nm), which is of great interests for radiation lithography. Among those promising advanced materials, particularly organometallic tin (organotin) compounds can provide photoresist patterning with significant advantages, such as improved resolution, sensitivity, etch resistance, and lower line width/edge roughness without pattern collapse because of strong EUV radiation adsorption of tin, which have been demonstrated.

Organotin compounds have been demonstrated as EUV photoresists, which provide promising approach for the development of further smaller features such as <7 nm. However, after storage, the poor stability, solubility, and short shelf time with aggregation or precipitation formation have become severe issues for distribution and application in photolithography patterning. In order to overcome the age and low stability of as-formed organotin photoresist composition, organic molecules containing functional groups, such as —SH, —OH, —COOH, —NH₂, or phosphine, can be used as additives to stabilize organotin photoresist including clusters or nanoclusters with improved stability and/or solubility. The organic molecules comprise organic thiol, organic alcohol, organic amine, organic amide, organic carboxylic acid, organic phosphine, phosphine oxide, or phosphonic acid, which can be adsorbed, grafted, immobilized, anchored, or coordinated on organotin photoresists to avoid potential aggregation or precipitation. After exposure, the exposed portion of organic molecules stabilized organotin photoresists may convert to polynuclear oxo-hydroxide network or metal oxides with poor solubility in solvents. While the unexposed portion of photoresists may be removed by developers.

### SUMMARY

In a first aspect, the present invention pertains to organotin photoresist composition for actinic radiation and a method of stabilization, wherein organotin photoresist composition comprises a (stannocenyl)tin compound, a solvent, and an additive. Stannocenyl comprises bis(cyclopentadienyl)tin, or substituted bis(cyclopentadienyl)tin, wherein cyclopentadienyl group includes cyclopentadienyl C₅H₅ group, and/or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group. In addition, (stannocenyl)tin compounds also may be used as precursors for photolithography or preparation of organotin photoresists.

In another aspect, the invention pertains to radiation sensitive (stannocenyl)tin compound photoresists, wherein (stannocenyl)tin compound is one or more selected from below:

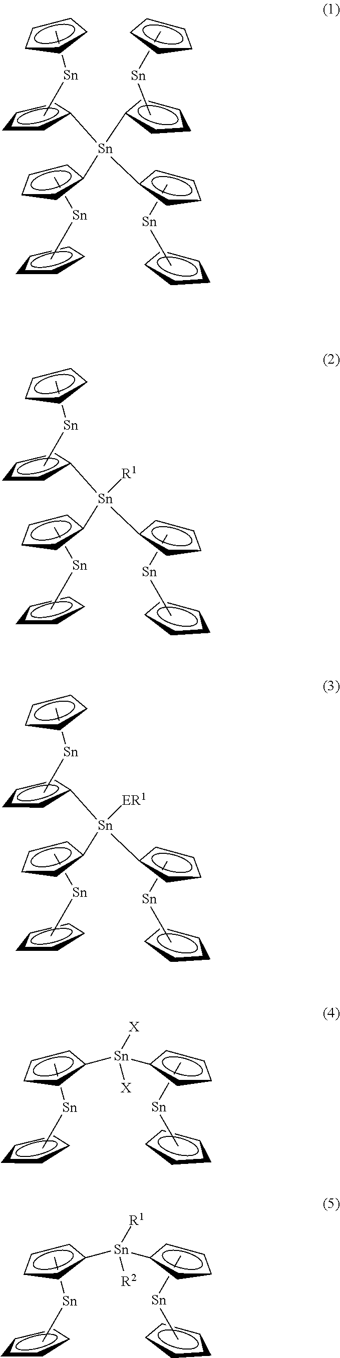

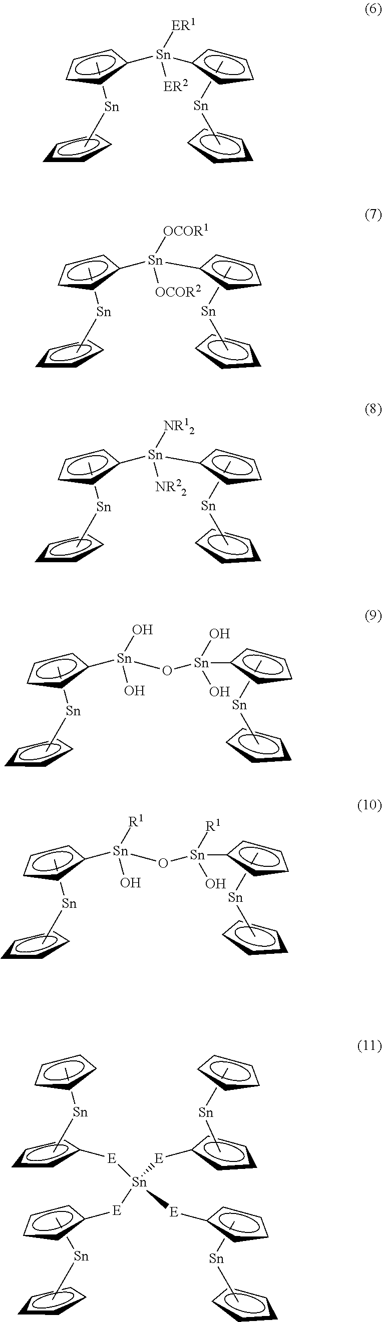

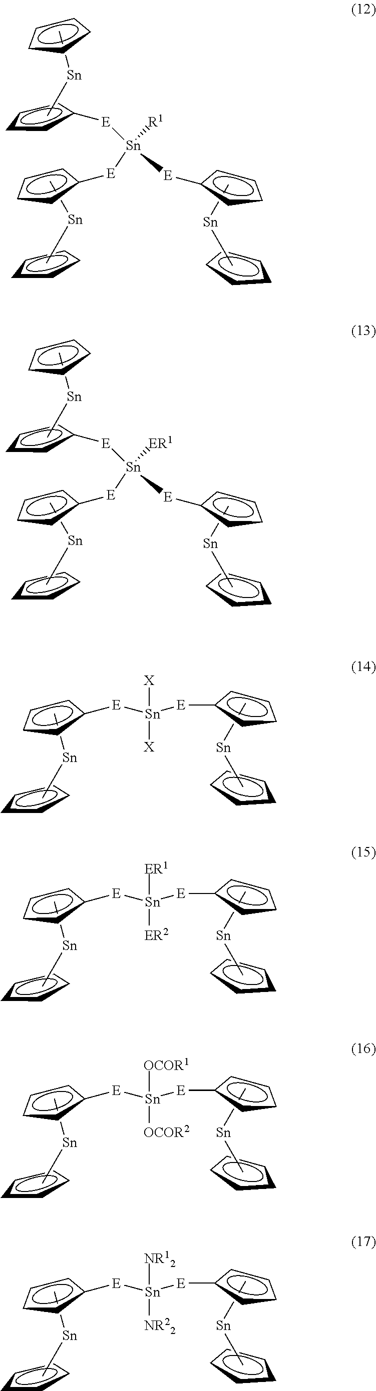

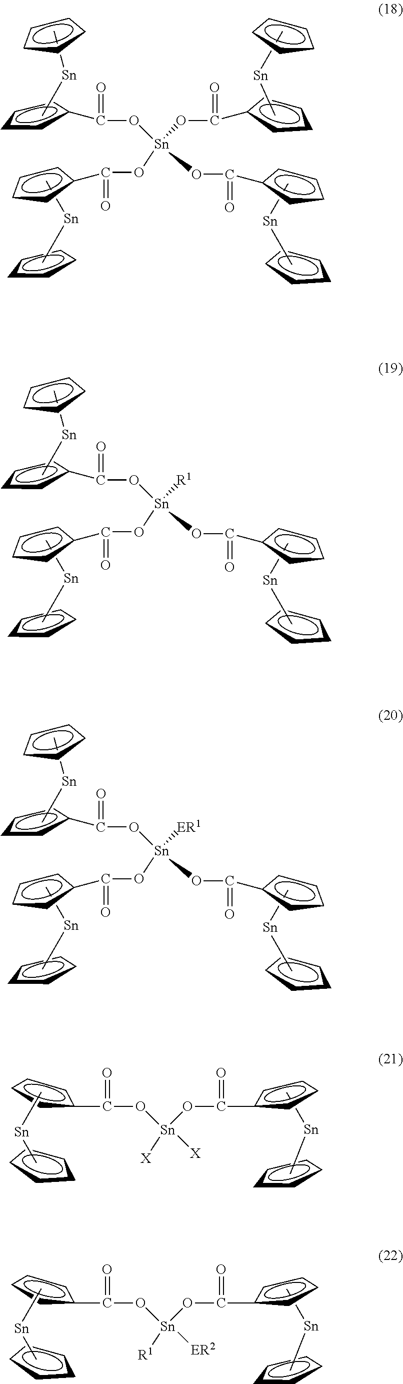

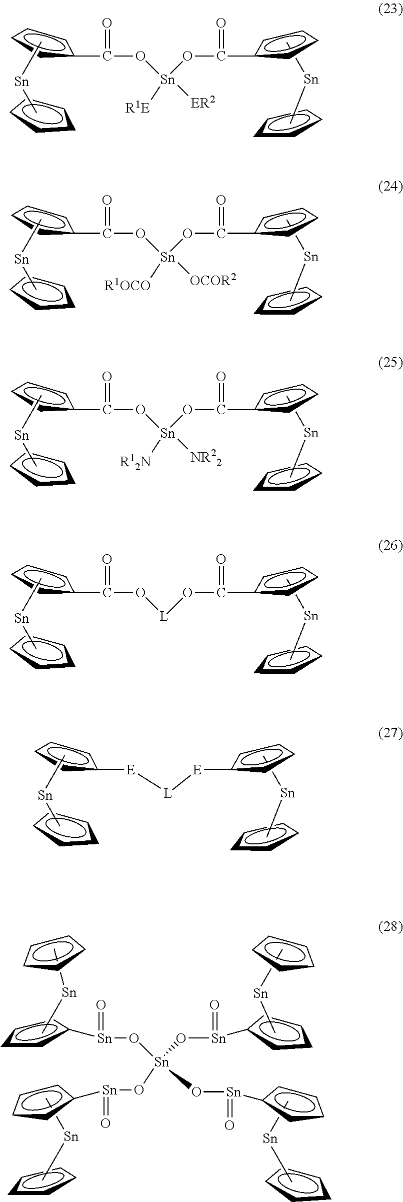

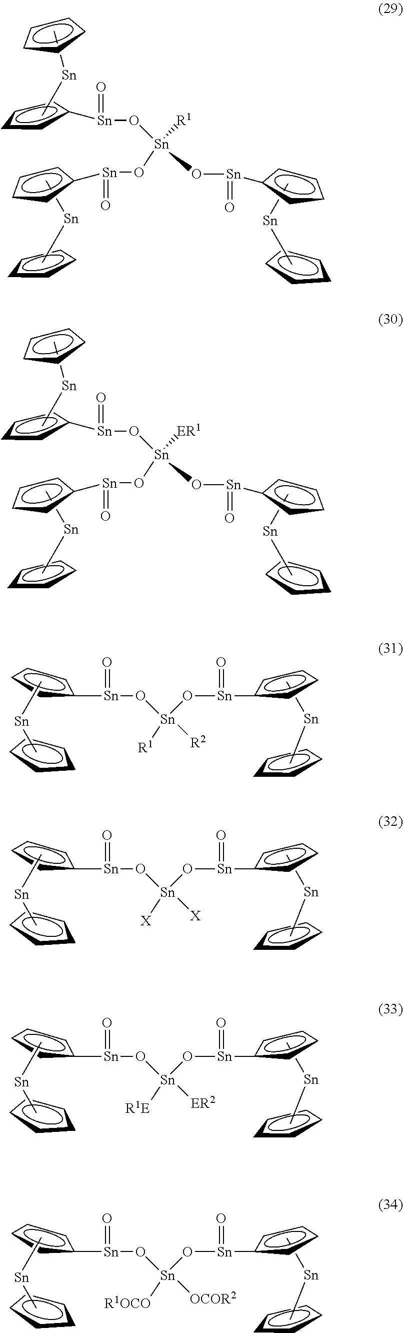

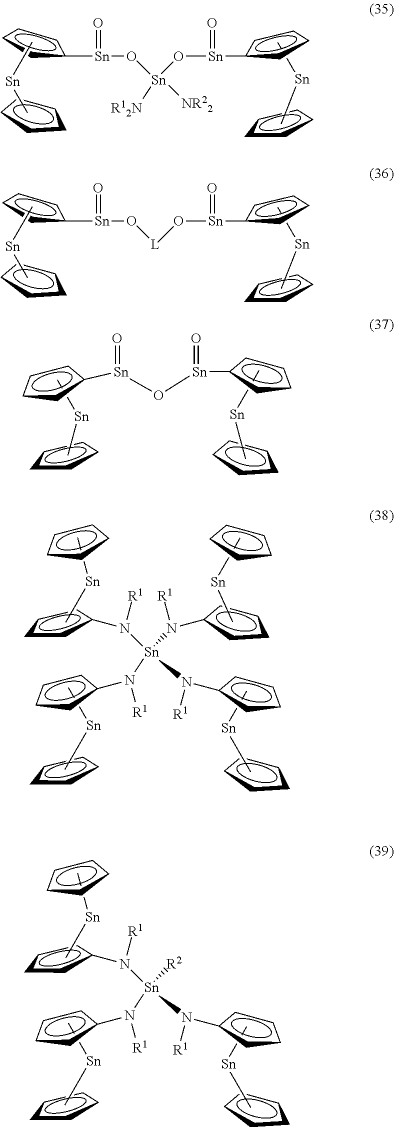

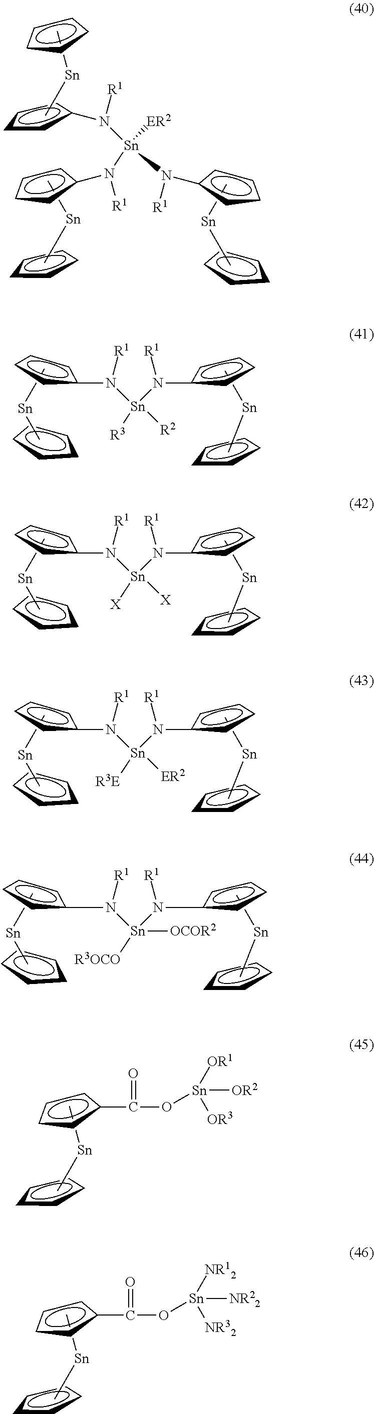

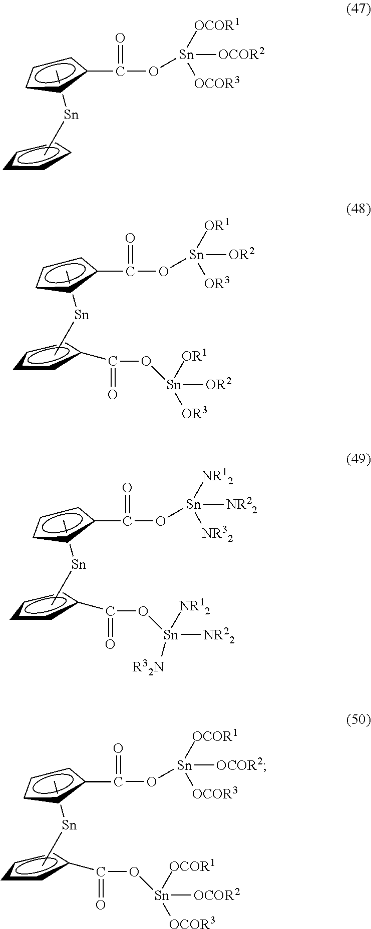

wherein R¹, R², R³, are each independently H, a substituted or unsubstituted alkyl, alkenyl, alkynyl, cycloalkyl, or cycloalkenyl group with 1 to 20 carbon atoms, or substituted or unsubstituted aryl group with 6-20 carbon atoms, E=O, S, Se, or Te, X=F, Cl, Br, or I, L is a substituted or unsubstituted alkyl, alkenyl, alkylene, alkynyl, cycloalkyl, or cycloalkenyl group with 1 to 20 carbon atoms, or a substituted or unsubstituted aryl group with 6-20 carbon atoms.

In a further aspect, the present invention pertains to a method of stabilization; wherein organic molecules as additives stabilize (stannocenyl)tin photoresist for photolithography patterning. The stabilization from organic molecular additives may overcome the disadvantages like poor stability and solubility, and/or short shelf time from non-stabilized conventional organotin photoresists. The method of stabilization comprises the addition of organic additive to the solution of as-formed organotin compounds, particularly organotin clusters, and to prevent from aggregation occurred or precipitate formation. The aggregation or precipitation can lead to scums or defects on the surface of substrates during photolithography patterning. The organic molecular additives contain various functional groups, such as —SH, —OH, —NH₂, —COOH, —CONH₂, including but not limited to, organic thiol, organic alcohol, organic amine, organic amide, organic carboxylic acid, organic phosphine, phosphine oxide, or phosphonic acid.

In another aspect, the invention pertains to radiation sensitive organometallic sandwich stannocene (Sc) (η⁵-C₅H₅)₂Sn or bis(cyclopentadienyl)tin as parent molecule to synthesize (stannocenyl)tin compounds as photoresists or precursors represented by chemical formulas (1)-(50) with standard Schlenk techniques. The mono-lithiation or bi-lithiation of cyclopentadienyl ring of stannocene is performed through the reactions of stannocene with appropriate amount of strong bases, such as n-BuLi, or t-BuLi, under ambient conditions. The as-formed mono-lithiation (η⁵-C₅H₄Li)Sn(η⁵-C₅H₅) or bi-lithiation (η⁵-C₅H₄Li)Sn(η⁵-C₅H₄Li) then reacts with appropriate reagents, such as SnCl₄, RSnCl₃, R₂SnCl₂, R₃SnCl, amine, Me₃SiOOSiMe₃, S₈, Se, Te powder, or CO₂ under ambient conditions to afford the desired products as photoresists or precursors.

In other aspects, the present invention is to provide preparation and purification methodology of (stannocenyl)tin compounds with high purity for photolithography (e.g., EUV, <7 nm). The purification methods include but not limited to distillation, extraction, filtration, recrystallization, column chromatography, coordination, sublimation, or combinations thereof.

The present invention is further to provide alternative organotin (stannocenyl)tin compound photoresists with higher resolution, sensitivity, and lower line width roughness without pattern collapse during microelectronic patterning. The photosensitivity, thermostability, and uniformity of organotin photoresist compositions determine high resolution and efficiency of photoresist for photolithography. The present invention is to provide improved stability, solubility, uniformity, and shelf life of organic molecules stabilized (stannocenyl)tin compound photoresist compositions for substrate surface coating without aggregation, precipitation, or age.

In a further aspect, the invention relates to radiation sensitive (stannocenyl)tin photoresist composition, which can be efficiently patterned after exposure to extreme ultraviolet radiation (EUV), deep ultraviolet radiation (DUV), electron beam radiation, X-ray radiation, or ion-beam radiation, or other likes to form high resolution patterns with low line width roughness, high resolution, low dose and large contrast, such as for <7 nm.

### BRIEF DESCRIPTION OF THE DRAWINGS

FIG. 1 illustrates a flowchart of organotin photoresist radiation photolithography patterning processing on the surface of semiconductor substrate surface.

### DETAILED DESCRIPTION

The present invention pertains to organotin photoresist composition and a method of stabilization, wherein organotin photoresist composition comprises a (stannocenyl)tin compound, a solvent, and an additive. Stannocenyl comprises organometallic bis(cyclopentadienyl)tin, or substituted bis(cyclopentadienyl)tin. The present invention is to provide the stabilization method for organotin photoresists suitable for EUV lithography (e.g. <7 nm). The method of stabilization comprises applying organic molecules as additives to stabilize (stannocenyl)tin compounds, particularly clusters. The present invention is further to provide organic molecules stabilized organotin photoresists with higher resolution, sensitivity, solubility, stability, shelf life, and lower line width roughness without pattern collapse during microelectronic patterning. The photosensitivity and thermostability of organotin photoresists determine high resolution and efficiency for photolithography patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms. The terms “alkenyl, alkynyl, cycloalkyl” refers to hydrocarbon of 1 to 20 carbon atoms. The term “aryl” refers to unsubstituted or substituted aromatic group with 6-20 carbon atoms. The substituted group include, but not limited to, amide, amine, cyano, ether, cyclic ether, ester, cyclic ester, halide, imine, nitro, silyl, thiol, or carbonyl group. The term “alkylene” refers to a saturated divalent hydrocarbons by removal of two hydrogen atoms from a saturated hydrocarbons of 1 to 20 carbon atoms, e.g., methylene (—CH₂—), ethylene (—CH₂CH₂—), propylene (—CH₂CH₂CH₂—), or the like.

The term “amine” refers to primary (—NH₂), secondary (—NHR), tertiary (—NR₂) amine group. The term “cyclic amine” refers to [R—NH-R′], wherein [R-R′] is cyclic substituted and unsubstituted C₃ to C₈ organic groups, including, but not limited to:

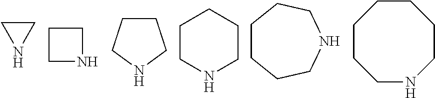

The term “ether” refers to the R—O-R′ group. The term “cyclic ether” refers to the [R—O-R′], wherein [R-R′] is cyclic substituted and unsubstituted C₃ to C₈ organic groups, e.g.,

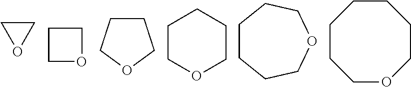

The term “ester” refers to the R-(C═O)—O—R′ group. The term “cyclic ester” refers to the [R-(C═O)—O—R′], wherein [R-R′] is cyclic substituted and unsubstituted C₄ to C₈ organic groups, e.g.,

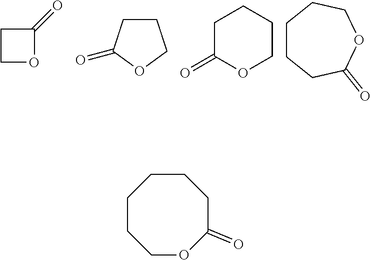

The term “halide” refers to the F, Cl, Br, or I. The term “nitro” refers to the —NO₂. The term “silyl” refers to the —SiR—, —SiR₂—, or —SiR₃ group. The term “thiol” refers to —SH group. The term “carbonyl” refers to the —C═O group. The term “oxo” refers to —O—, or ═O. In the above described, R, R′ are independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

In the present disclosure, the term “substituted” refers to replacement of a hydrogen atom with a C1 to C20 alkyl group, a C1 to C20 alkene group, a C1 to C20 alkyne group, a C1 to C20 cycloalkyl group, a C6 to C20 aryl group, or other relevant groups such as amino, cyano, ether, ester, halide, nitro, silyl, thiol, or carbonyl group.

The terms “η” refers to one carbon atom bonded to one metal atom. The terms “η²” refers to two carbon atoms bonded to one metal atom. The terms “η³” refers to three carbon atoms bonded to one metal atom. The terms “η⁴” refers to four carbon atoms bonded to one metal atom. The terms “η⁵” refers to five carbon atoms bonded to one metal atom.

EUV lithography is under the development for the mass production of next generation <7 nm node. EUV photoresists are required to achieve higher performance, higher sensitivity and resolution, and cost reduction. EUV light has been applied for photolithography at about 13.5 nm. The EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists encounter critical issues, such as poor EUV light adsorption, low resolution, high line edge roughness (LER), increased pattern collapses and defects. In order to overcome the disadvantages from conventional organic polymer photoresists or inorganic photoresists, novel organometallic photoresists, or organometallic photosensitive compositions, particularly for EUV, have been called for.

Organometallic photoresists are used in EUV lithography because metals have high adsorption capacity of EUV radiation. Radiation sensitivity and thermal-, oxygen- and moisture-stability are important for organometallic photoresists. In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the lithography performance, pattern collapse and increase defects.

In general, metal central plays the key role in determining the absorption of photo radiation. The physical and chemical properties of organometallic compounds which are suitable for photoresists determine the relevant properties for photolithography, particularly for EUV and DUV, wherein bond dissociated energy (BDE) of M-C(metal-carbon bond) plays the key role. M is metal, including but not limited to, tin (Sn), indium (In), antimony (Sb), bismuth (Bi), manganese (Mn), vanadium (V), titanium (Ti), chromium (Cr), selenium (Se), tellurium (Te), zirconium (Zr), hafnium (Hf), gallium (Ga), or germanium (Ge). Particularly, organotin photoresists are suitable for EUV or DUV photolithography patterning.

Meanwhile for organometallic compounds, the metal-bonded organic ligands (M-R, M=metal, R=cleavable/hydrolysable organic ligands) may also affect the relevant UV absorption through M-C bonding.

Tin atom provides strong absorption of extreme ultraviolet (EUV) light at 13.5 nm, therein tin cations can be selected based on the desired radiation and absorption cross section. The organic ligand bonded to tin also has absorption of EUV light. The tuning and modification of organic ligands can change the resolution, sensitivity and radiation absorption, and material properties.

In some embodiments, organotin photoresist comprises small organometallic tin compound, or organotin cluster with large molecular weight. In some embodiments, the small organometallic tin compound contain one, two, or three tin atoms. In some embodiments, organotin cluster contain more than three tin atoms, for example, twelve.

The organotin photoresists comprise organometallic stannocenyl unit, organic ligands, Sn—C bond, or Sn—O bond, or Sn—S bond, or Sn—Se bond, or Sn—Te bond, or Sn—N bond, or Sn—O—Sn bond providing desirable radiation sensitive and stabilization for precursor metal cations. The organotin photoresists possess excellent properties for photolithographic patterning.

(Stannocenyl)tin compound photoresist compositions containing cyclopentadienyl or substituted-cyclopentadienyl group, according to embodiments of the present disclosure, may have improved etch resistance, sensitivity and resolution, compared with related conventional organic polymer or inorganic photoresists, wherein oxygen, nitrogen, or various groups are bonded to tin metal as described above.

Organotin photoresist layer is patterned by exposure to actinic radiation. Typically, the chemical properties of the photoresist regions struck by incident radiation change in a manner that depends on the type of photoresist used. Photoresist can be positive resist or negative resist. In some embodiments, positive resist refer to a photoresist material that when exposed to radiation becomes soluble in a developer, while the region of the photoresist that is non-exposed (or exposed less) is insoluble in the developer. In some embodiments, on the contrary, negative resist refers to a photoresist material that when exposed to radiation becomes insoluble in the developer, while the region of the photoresist that is non-exposed (or exposed less) is soluble in the developer.

Examples of specific organotin compounds as photoresists that may be used in implementations of the invention, are represented by chemical formulas (1)-(50) as the following:

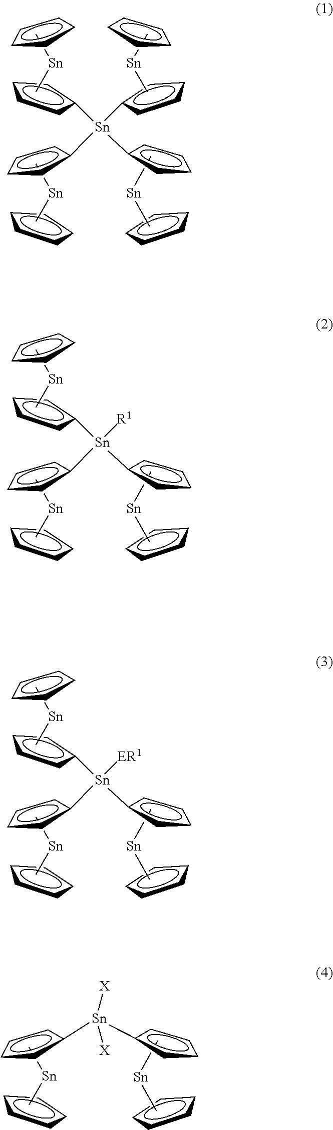

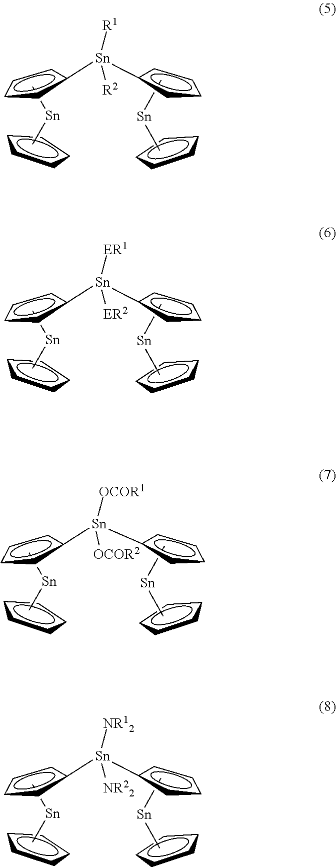

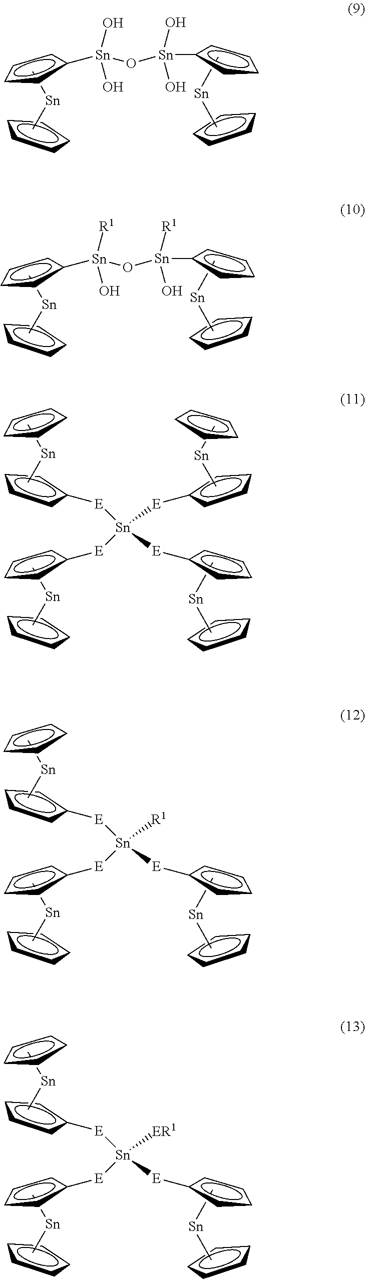

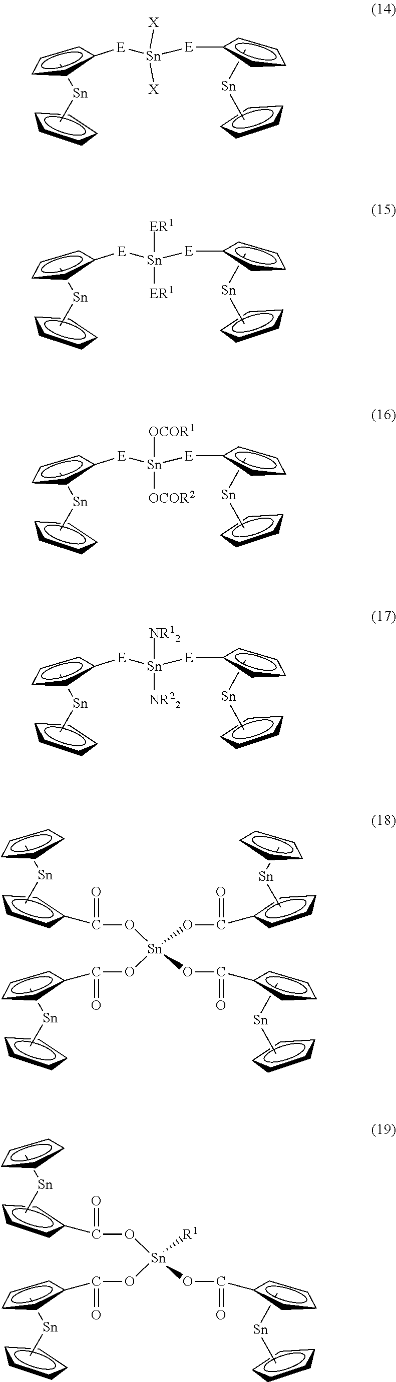

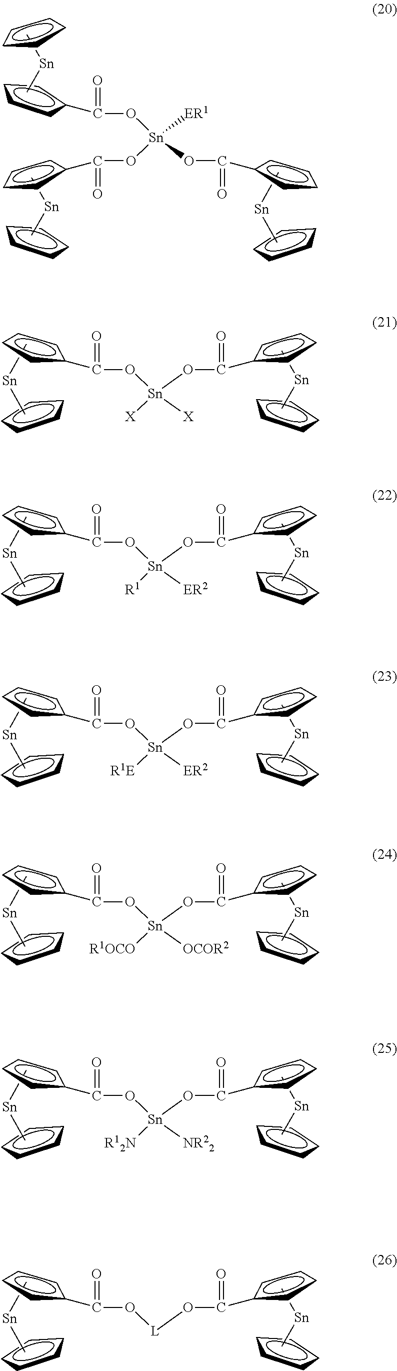

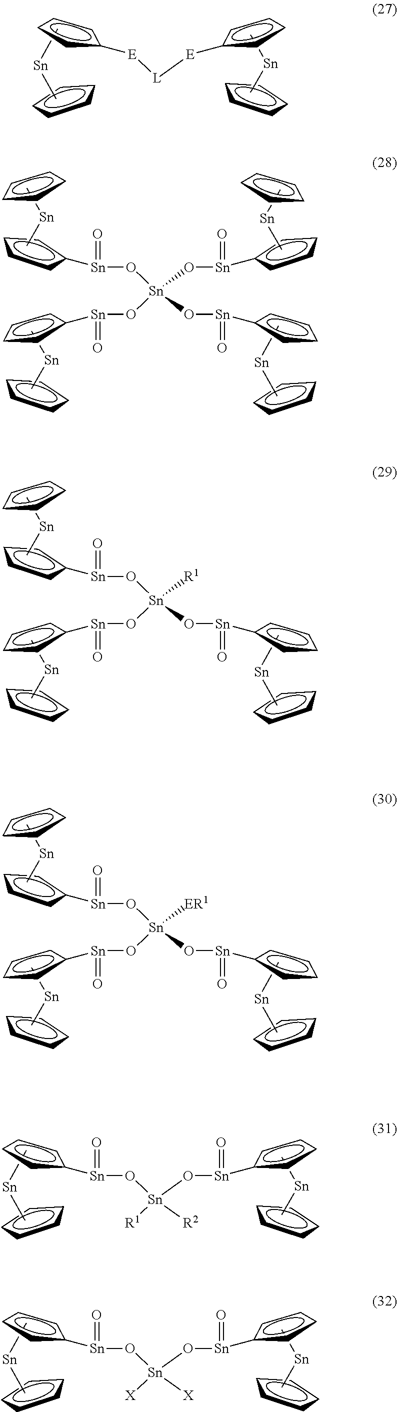

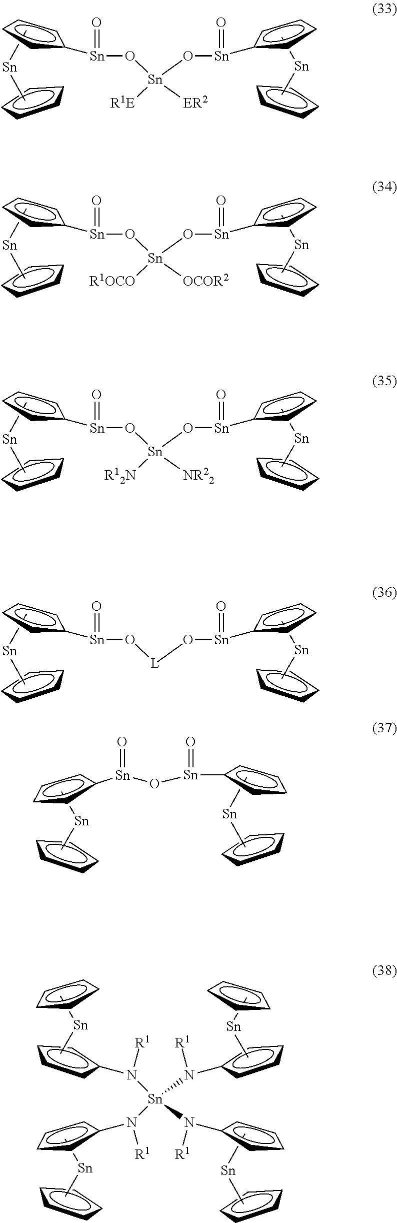

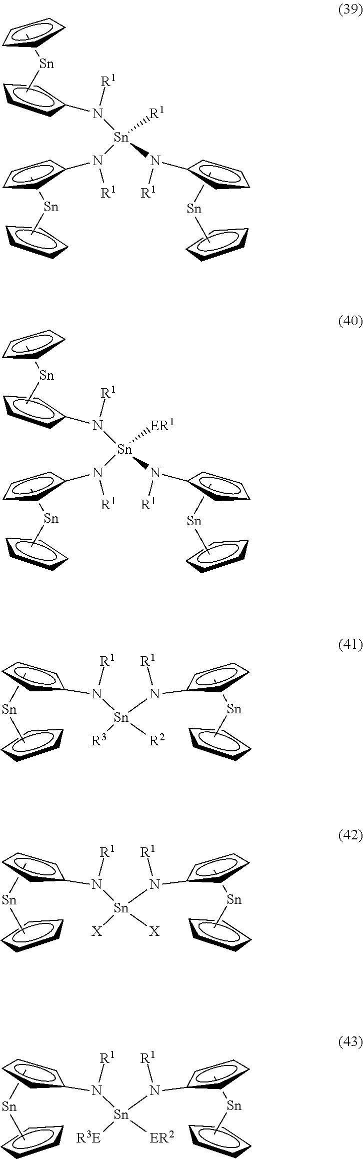

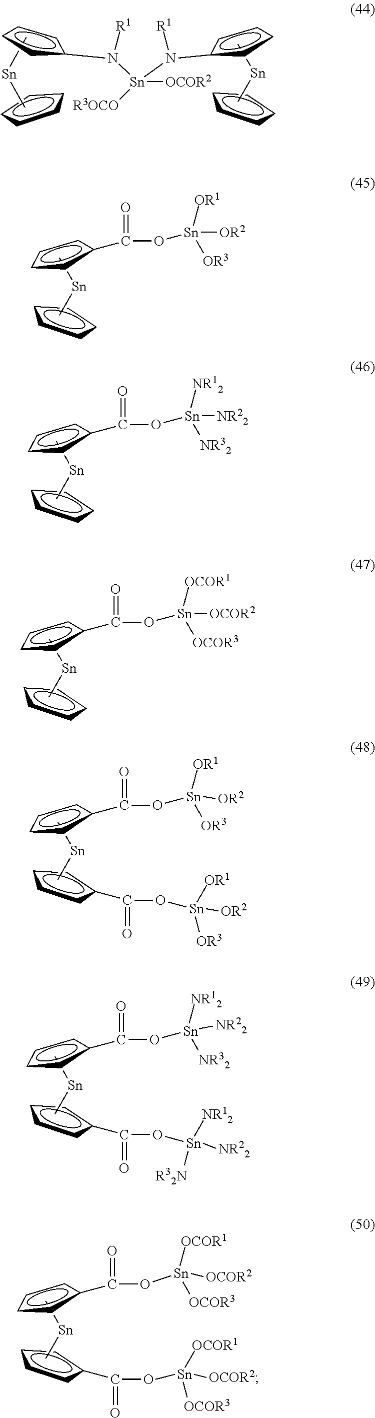

wherein R¹, R², R³ are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te; X=F, Cl, Br, or I.

L is a substituted or unsubstituted alkyl, alkylene, alkenyl, alkynyl, cycloalkyl, or cycloalkenyl group with 1 to 20 carbon atoms, or a substituted or unsaturated aryl group with 6-20 carbon atoms, for example, methylene, or ethylene.

Cycloalkenyl group comprises a substituted and unsubstituted C₄ to C₈ cyclic aliphatic unsaturated organic groups including at least one double bond, for example,

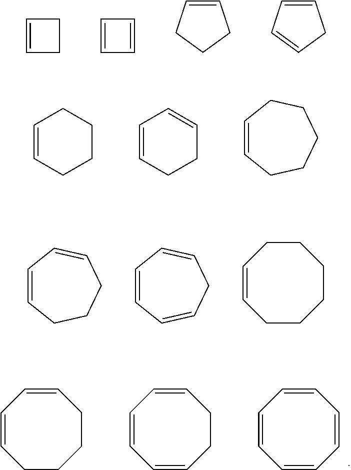

In some embodiments, organotin photoresists according to embodiments of the present disclosure may be represented by at least one of examples.

As one of ordinary skill in the art will recognize, the chemical compounds listed here are merely intended as illustrated examples of the organotin compound photoresists, and are not intended to limit the embodiments to only those organotin compound photoresists specifically described. Rather, any suitable organotin compound photoresist may be used, and all such organotin compound photoresists are fully intended to be included within the scope of the present embodiments.

The organotin compounds represented by Chemical Formulas (1)-(50) contain stannocenyl group, wherein stannocenyl comprises bis(cyclopentadienyl)tin, or substituted bis(cyclopentadienyl)tin, wherein cyclopentadienyl comprises cyclopentadienyl C₅H₅(Cp) group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

The invention pertains to methods for preparation and purification of organometallic (stannocenyl)tin compounds represented by Chemical Formulas (1)-(50), or organic molecules stabilized organotin photoresists. All chemical manipulations, including preparation and purification, are performed under an inert atmosphere of purified nitrogen or argon in dry and degassed solvents by employing standard Schlenk techniques. The methods for purification of organometallic (stannocenyl)tin compounds, organotin photoresists, or organic molecules stabilized organotin photoresists comprise distillation, extraction, filtration, recrystallization, column chromatography, coordination, sublimation, or combinations thereof. In some embodiments, recrystallization may result in single crystals, which are suitable for X-ray diffraction analysis to determine the molecular structures.

Organometallic sandwich stannocene (η⁵-C₅H₅)₂Sn (Cp₂Sn, or bis(cyclopentadienyl)tin) as parent molecule can be carried out lithiation with strong bases at one or two cyclopentadienyl rings, for the preparation of organometallic (stannocenyl)tin compounds represented by Chemical Formulas (1)-(50) with appropriate reagents.

Wherein strong bases include, but not limited to, methyllithium (MeLi), n-butyllithium (n-BuLi), or t-butyllithium (t-BuLi). The lithiation of one or two cyclopentadienyl rings depends on the reaction condition, for example, the amount of bases, solvent, temperature, or addition rate.

In exemplary embodiments, (stannocenyl)tin compounds represented by Chemical Formulas (1)-(50) can be synthesized from the reactions of mono-lithiation product (η⁵-C₅H₄Li)Sn(η⁵-C₅H₅), or bi-lithiation product (η⁵-C₅H₄Li)Sn(η⁵-C₅H₄Li) with relevant reagents, such as SnCl₄, RSnCl₃, R₂SnCl₂, R₃SnCl, amine, Me₃SiOOSiMe₃, S₈, Se powder, Te powder, or CO₂ with standard Schlenk techniques, wherein R includes, but not limited to a substituted or unsubstituted alkyl, alkenyl, alkylene, alkynyl, cycloalkyl, or cycloalkenyl group with 1 to 20 carbon atoms, or a substituted or unsubstituted aryl group with 6-20 carbon atoms.

In an example embodiment, organotin compound [(C₅H₅)Sn(C₅H₄)]₂Sn(^{t}Bu)₂ can be prepared according to the following method:

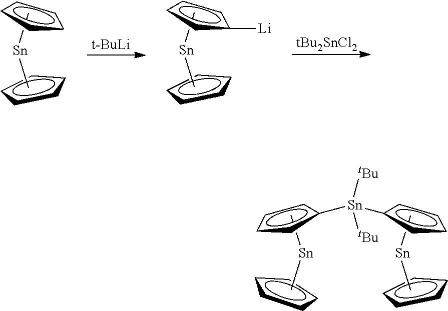

A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In another example embodiment, organotin compound [(C₅H₅)Sn(C₅H₄S)]₃Sn(^{t}Bu) can be prepared according to the following method:

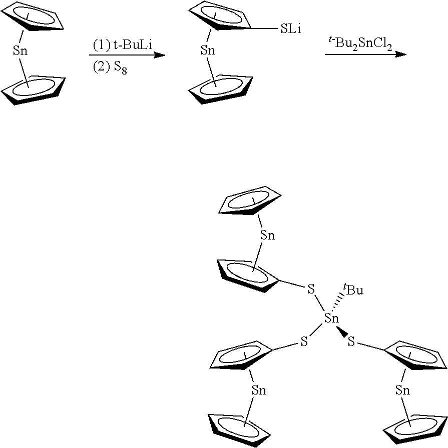

A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In the present invention, (stannocenyl)tin compounds represented by Chemical Formulas (1)-(50) may contain four, three, two, or one stannocenyl group with various functional groups, such as tetrakis(stannocenyl)tin [(C₅H₅)Sn(C₅H₄)]₄Sn represented by chemical formula (1), or [(C₅H₅)Sn(C₅H₄E)]₄Sn (E=O, S, Se or Te) represented by chemical formula (11).

Cyclopentadienyl group (C₅R₅, or Cp) may impart photosensitivity to the compounds, and the Cₚ-Sn bond formed may promote suitable solubility in an organic solvent to the organometallic (stannocenyl)tin compounds. Accordingly, these Cₚ-Sn bond containing organometallic (stannocenyl)tin compounds according to an embodiment may have improved sensitivity, resolution and stability, and may suitable for EUV photoresists, and/or the precursors for EUV lithography patterning.

The organotin compounds represented by chemical formulas (1)-(50) contain Sn—C, or Sn—N, or Sn—O, or Sn—S, or Sn—Se, or Sn—Te bond with different bond dissociation energy (BDE), and sensitivity to extreme ultraviolet light, may adsorb extreme ultraviolet light at 13.5 nm.

The organotin compounds represented by chemical formulas (1)-(50) contain cyclopentadienyl-Sn bond (Cₚ-Sn bond). Cₚ-Sn bond is sensitive to UV light and occurs the radiation disruption to generate free radical when exposures to UV light, which has been demonstrated, for example, P. J. Baker, A. G. Davies, M.-W. Tse, “The photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅-Sn) compounds, i.e., C₅H₅SnMe₃, C₅H₅SnBu₃, (C₅H₅)₂SnBu₂, C₅HsSnCl₃, (C₅H₅)₂SnCl₂, (C₅H₅)₃SnCl, and (C₅H₅)₄Sn in toluene showed strong EPR spectra of the C₅H₅• radical. This study demonstrated cyclopentadienyl (C₅H₅) group or substituted cyclopentadienyl (C₅R₅) group has higher UV light sensitivity compared with alkyl (e.g., methyl, butyl) group under identical condition. This property is beneficial for decreasing EUV light dose and increasing resolution.

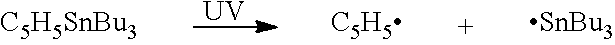

(Stannocenyl)tin photoresists contain cyclopentadienyl or substituted cyclopentadienyl group, π bond, C—Sn bond and related interaction and may have excellent sensitivity to high energy light (e.g., EUV, or DUV) due to tin adsorption high energy EUV ray at 13.5 nm. Accordingly, the related solution compositions may have improved resolution, sensitivity, and stability compared with organic polymer or inorganic photoresists such as metal oxides.

(Stannocenyl)tin compound photoresists may have excellent sensitivity to EUV radiation light due to the tin adsorption high energy EUV ray at 13.5 nm (low expose dose photoresist, e.g., <20 mJ/cm²), and the disruption of Cₚ-Sn bond to form free radical, tin oxide and relative products, and toughness; low or free pattern defectivity at nanoscale. Accordingly, (stannocenyl)tin compound photoresist compositions may have tight pitch (e.g., <10 nm), and may sustain the yield and deliver high resolution.

(Stannocenyl)tin compound photoresists are soluble in appropriate organic solvents with improved uniformity for further photolithography pattern processing. The solution of organotin photoresist can be formed by dissolving (stannocenyl)tin photoresists in organic solvents, including but not limit to, pentane, hexane, cyclohexane, dichlomethane, chloroform, tetrahydrofuran, dimethoxyethane, dimethylformamide, dimethyl sulfoxide, alcohols (e.g., 4-methyl-2-pentenol, methanol, ethanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. A person of ordinary skills in the art will recognize that the choice of solvents and solution composition components within the explicit ranges of above are contemplated and are within the present disclosure.

The organotin photoresist composition may include 0.1 wt % to 60 wt % of the organometallic (stannocenyl)tin compounds represented by Chemical Formulas (1)-(50), based on the total weight of the organotin photoresist composition.

In some embodiments, (stannocenyl)tin compounds represented by chemical formulas (1)-(50) may also be used as precursors to form organotin photoresists, for example, hydrolysis with water or moisture, or condensation reaction with organic acids (e.g., formic acid, acetic acid, citric acid, propionic acid, isovaleric acid, butyric acid, valeric acid, caproic acid, glycolic acid, lactic acid, oxalic acid, or succinic acid) to form organotin photoresists. In some embodiments, (stannocenyl)tin compounds represented by chemical formulas (1)-(50) may be used as precursors for transparent conducting oxides, thermoelectric materials, or catalysts.

In some embodiments, organometallic (stannocenyl)tin compounds as precursors for preparation of organotin cluster photoresists, according to embodiments of the present disclosure, may contain hydrolysable functional groups, such as —OR, —SR, —SeR, —TeR, —X, —NR₂, or —OCO.

In some embodiments, the poor stability of conventional organotin photoresists in solution after aged would lead to aggregation or precipitation with short shelf life for photolithography, which then would result in scums or defects in photolithography patterning.

In some embodiments, the solubility of hydrolysis or condensation products like organotin nanoclusters in organic solvents like toluene, hexane, acetone, heptanone and 2-butanone is not satisfactory. Therefore, the filtration through membrane like 0.25 μm PTFE is required before spin-on coating on the surface of substrates. This indicates that size and uniformity of organotin clusters or nanoclusters are important for thin film generation and subsequent photolithography.

In some embodiments, a blend of organotin photoresists with distinct organic ligands provides further improvement in the photolithography patterning, compare with single component organotin compound photoresist.

In some embodiments, an organotin photoresist precursor solution deposits over a surface of substrate or layer to form photoresist layer through in situ hydrolysis with water, or alternative bases like tetramethyl ammonium hydroxide. Then baking of the formed photoresist layer at an elevated temperature result in hydrolysis of organotin compound and subsequent condensation to form organotin oxide hydroxide clusters. After exposure, patterning radiation causes Sn—C bond cleavage and crosslinking of the organotin oxide hydroxide clusters in the exposed portions of photoresists, and then resulted in a stable metal oxide (MOx).

In some embodiments, the stability of (stannocenyl)tin photoresists in solution can be improved by organic molecules as stabilizers. The organic molecules-stabilized (stannocenyl)tin photoresists possess improved stability, solubility, uniformity, or shelf life for photolithography.

In some embodiments, organic molecules stabilizers include, but not limited to, organic thiol, organic alcohol, organic amine, organic amide, organic carboxylic acid, organic phosphine, phosphine oxide, phosphonic acid, or a combination thereof.

In some embodiments, organic thiol includes, but not limited to, 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or a combination thereof.

In some embodiments, organic alcohol includes, but not limited to, 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or a combination thereof.

In some embodiments, organic amine includes, but not limited to, 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or a combination thereof.

In some embodiments, organic amide includes, but not limited to, decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or a combination thereof.

In some embodiments, organic carboxylic acid includes, but not limited to, oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or a combination thereof.

In some embodiments, organic phosphine, phosphine oxide, or phosphonic acid, include, but not limited to, trioctylphosphine, tributylphosphine, tris(dimethylamino)phosphine, tris(diethylamino)phosphine, trioctylphospine oxide, hexylphosphonic acid, octadecylphosphonic acid, 11-undecenyl phosphonic acid, or a combination thereof.

In some embodiments, (stannocenyl)tin photoresists comprise functional groups, including but not limited to, ether, thiol, silyl, keto, cyano, carbonyl, or halogenated groups, or a combination thereof.

In some embodiments, organic molecules stabilizers may be adsorbed, grafted, immobilized, anchored, or coordinated on (stannocenyl)tin photoresists as supports. For example, organic thiol or thiolate may coordinate with tin of (stannocenyl)tin to form Sn—S bond.

The organic molecules stabilized (stannocenyl)tin photoresist composition according to an embodiment can be performed by the addition of organic molecular stabilizer to the solution of (stannocenyl)tin compound under ambient condition, e.g., temperature range from −196 to 300° C., inert N₂ or Ar atmosphere, or air atmosphere, in organic solvent or water with various concentration. The addition of organic molecules stabilizers can be carried out during 0-24 hours after the generation of (stannocenyl)tin compound photoresist solution.

In some embodiments, organic molecules stabilized organotin photoresist can dissolve in appropriate organic solvents to form uniformed solution composition for deposition on the surface of substrate for photolithography patterning. The organic solvents include, but not limited to, aromatic solvents, pentane, hexane, cyclohexane, tetrahydrofuran, dimethoxyethane, alcohol, ether, ester, methylene chloride, chloroform, or combinations thereof.

In an exemplary embodiment, the preparation of organic thiol-stabilized (stannocenyl)tin photoresist can be represented by the preparation of dodecanethiolate-stabilized [(C₅H₅)Sn(C₅H₄S)]₃Sn(^{t}Bu), wherein 1-dodecanethiol was added to the solution of [(C₅H₅)Sn(C₅H₄S)]3Sn(^{t}Bu) in THF.

The solution composition of (stannocenyl)tin photoresists can be utilized for photolithography including deep ultraviolet radiation (DUV), extreme ultraviolet radiation (EUV), e-beam radiation, X-ray radiation, or ion-beam radiation for further processing and patterning.

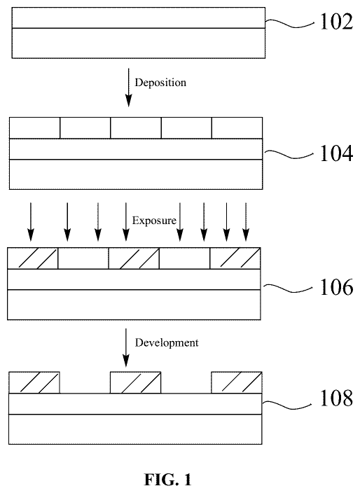

A method of forming photolithography pattern using the organotin photoresist composition is illustrated by FIG. 1. The (stannocenyl)tin photoresist composition deposites over a substrate 102 to form a thin photoresist layer 104; such as silicon, silicon oxide to form photoresist layer. After baking at appropriate temperature, the organotin photoresist layer is exposed to actinic radiation to form a latent pattern 106. After post-exposure baking, the latent is developed by the appropriate developer, such as aqueous basic/acid solutions or organic solvents, to produce the developed resist photolithography pattern 108. The formed latent pattern is developed by applying a developer to remove the unexposed, or exposed portion of photoresists to form a photolithography pattern.

The methods for deposition of organotin photoresists on a surface of semiconductor substrate include wet deposition like spin-on coating, spray coating, dip coating, vapor deposition, knife edge coating, or dry deposition like chemical vapor deposition (CVD), physical vapor deposition (PVD), atomic layer deposition (ALD), or other approaches.

In some embodiments, after exposure, the exposed and unexposed portion of organotin photoresists possess different chemical and physical properties. Organic ligands of organotin photoresists can be cleaved to form metal oxide or polynuclear oxo/hydroxo network patterns. The unexposed portion of photoresists can be removed by the developer according to different features, solubility and properties. In an embodiment, the developer is a wet developer such as organic solvent, or aqueous solution. In another embodiment, the developer is a dry developer. In some embodiments, the developing method is sublimation or evaporation under high reduced pressure in the range of 0.00001 torr to 100 torr, and/or high temperature in the range of 20 to 200° C.

In addition, (stannocenyl)tin compound photoresist compositions patterning according to an embodiment is not necessarily limited to the negative tone image but may be formed to have a positive tone image.

The advantages of (stannocenyl)tin compound photoresist or organic molecular stabilized (stannocenyl)tin compound photoresist composition are obvious as above discussed, compared with organic molecular or organic polymer photoresist, or inorganic photoresists. However, it will be understood that not all the advantages have been necessarily discussed herein to include all embodiments or examples, other embodiments or examples may offer different advantages.

Hereinafter, the present invention is described in more details through Examples regarding the preparation of (stannocenyl)tin compounds as photoresists or precursors for organotin photoresist compositions for photolithography patterning, as well as the stabilization method of the present embodiments. However, the present invention is not limited by the Examples. A person of ordinary skills in the art will recognize that the samples and solution composition components within the explicit ranges of above are contemplated and are within the present disclosure.

### EXAMPLES

### Example 1

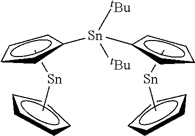

Synthesis of Sn(η⁵-C₅H₄)₂Sn^{t}Bu₂. At −78° C., a solution of ^{t}Bu₂SnCl₂ (486 mg, 1.6 mmol) in ether (20 mL) was added dropwise to a solution of (η⁵-C₅H₄Li)(η⁵-C₅H₅) (from 788 mg/3.3 mmol stannocene, and 2.1 mL/1.6 M, 3.36 mmol t-BuLi) in THF (100 mL) with vigorously stirring. After stirring overnight at room temperature, all the volatiles were removed in vacuo. The reside was extracted by toluene and filtered through a short pad of silicon. The filtrate was evaporated in vacuo to give the titled product. Yield: 460 mg, 61%. ¹H NMR (400.13 MHz, CDCl₃) δ=1.33 (s, 18H), 6.16 (s, 10H), 6.29 (m, 4H), 6.68 (m, 4H). EI-MS (70 eV): m/z 470 (M+).

### Example 2

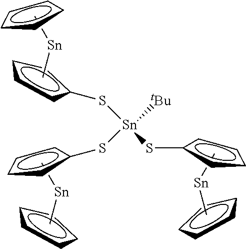

Synthesis of [(C₅H₅)Sn(C₅H₄S)]₃Sn^{t}Bu. At −78° C., to a solution of (η⁵-C₅H₅)Sn(η⁵-C₅H₄SLi) (916 mg, 3.3 mmol) in THF (100 mL), a solution of ^{t}BuSnCl₃ (310 mg, 1.1 mmol) in diethyl ether (20 mL) was added dropwise with vigorously stirring. After addition, the mixture was slowly warmed to room temperature and stirred overnight. Then the reaction solution was evaporated in vacuo. The obtained residue was extracted by toluene and filtered through a short pad of silicon. Removal of the solvent resulted in the titled product. Yield: 0.5 g, 46%. ¹H NMR (400.13 MHz, CDCL₃) δ=1.26 (s, 9H), 6.11 (s, 15H), 6.22 (m, 6H), 6.63 (m, 6H). EI-MS (70 eV): m/z 985 (M⁺).

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the sprit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin compound as photoresist for actinic radiation containing stannocenyl group is represented by chemical formulas (1)-(50) as below: 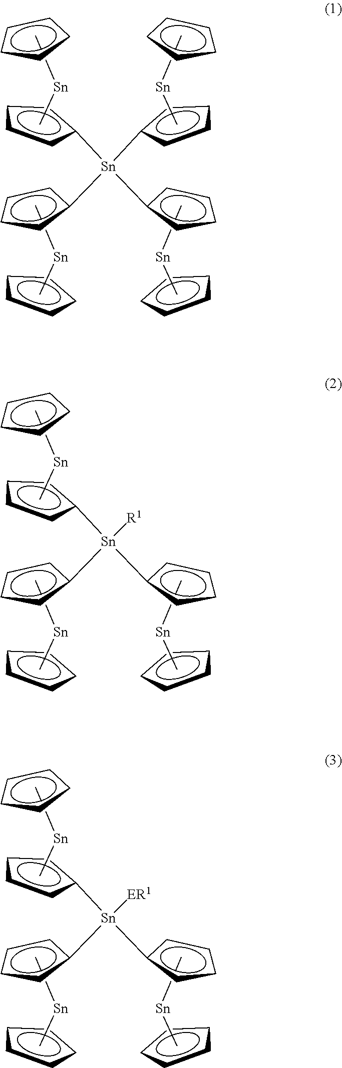 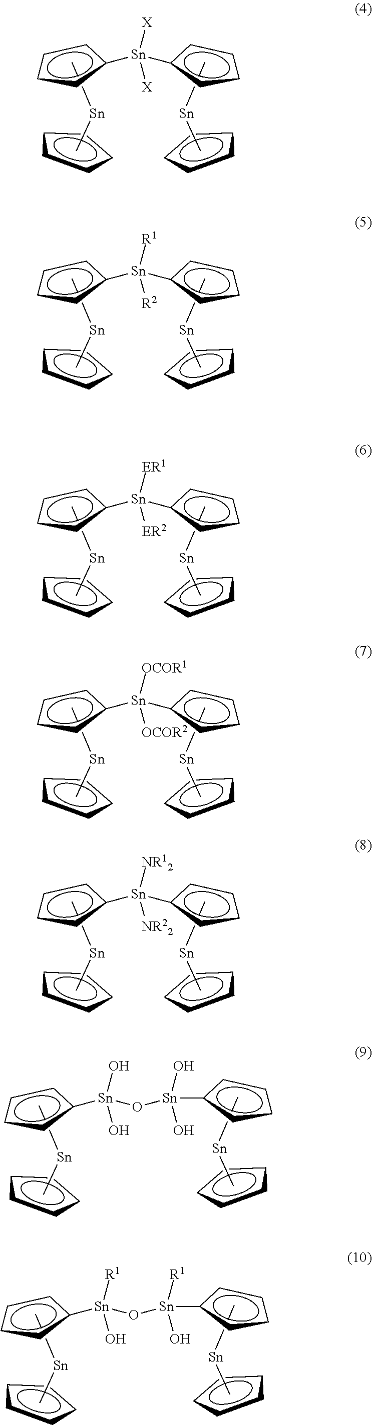 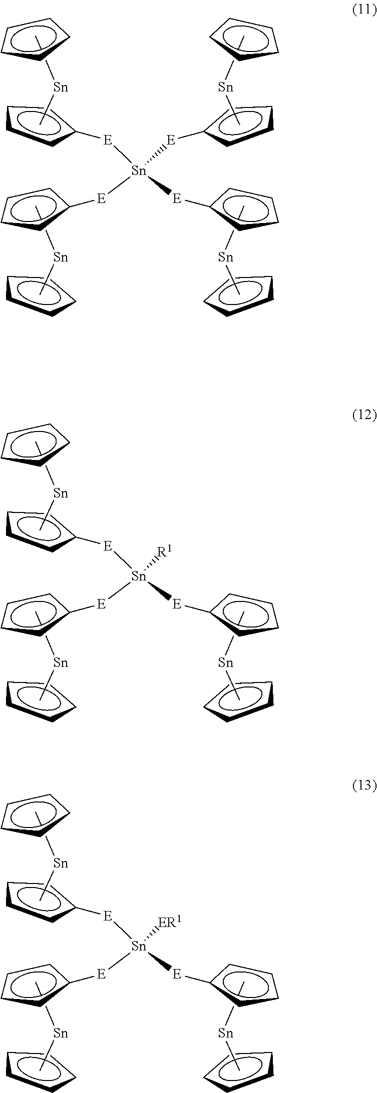 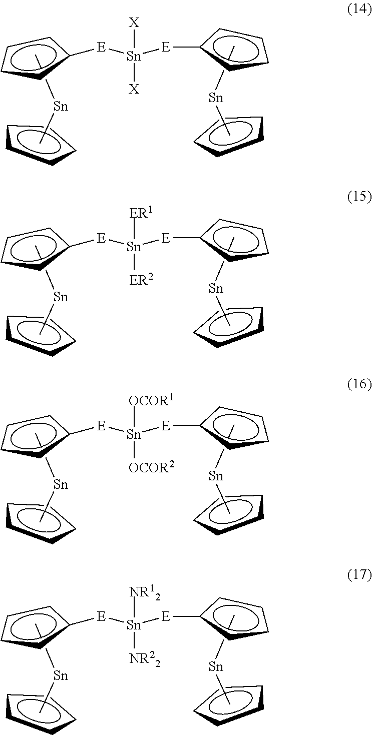 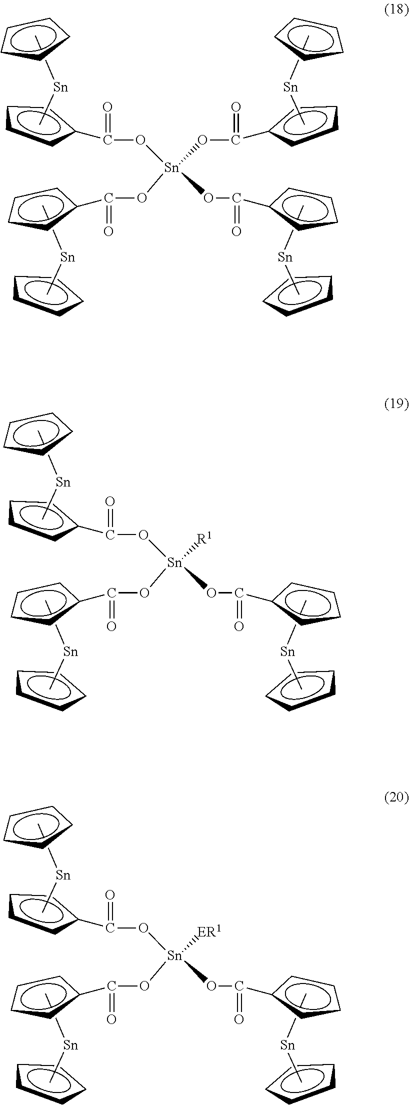 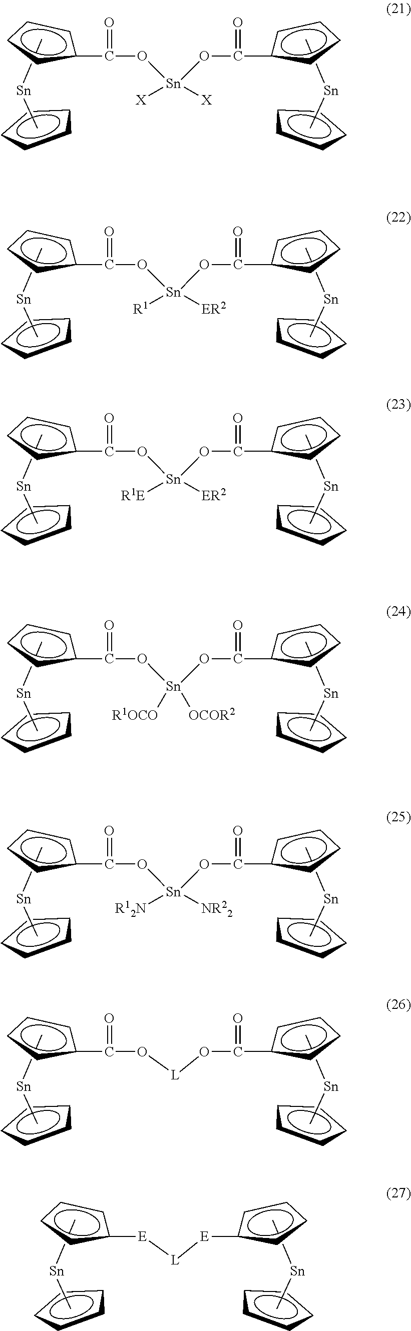 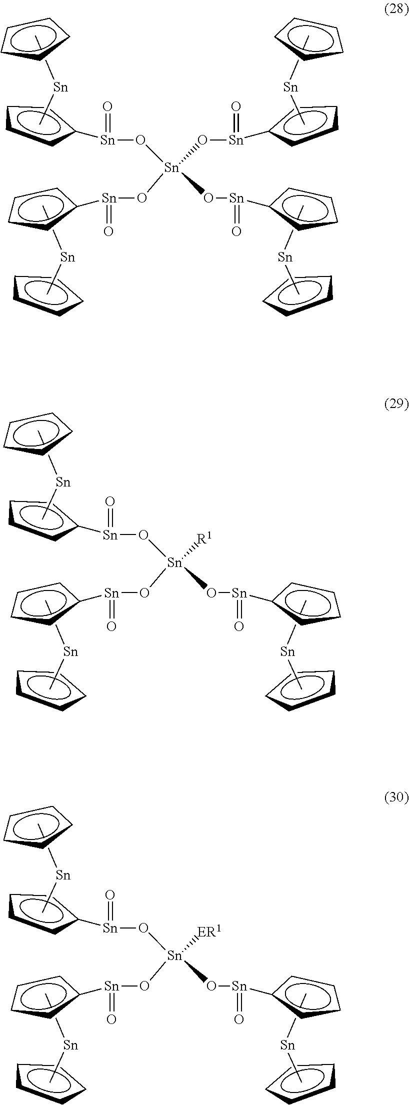 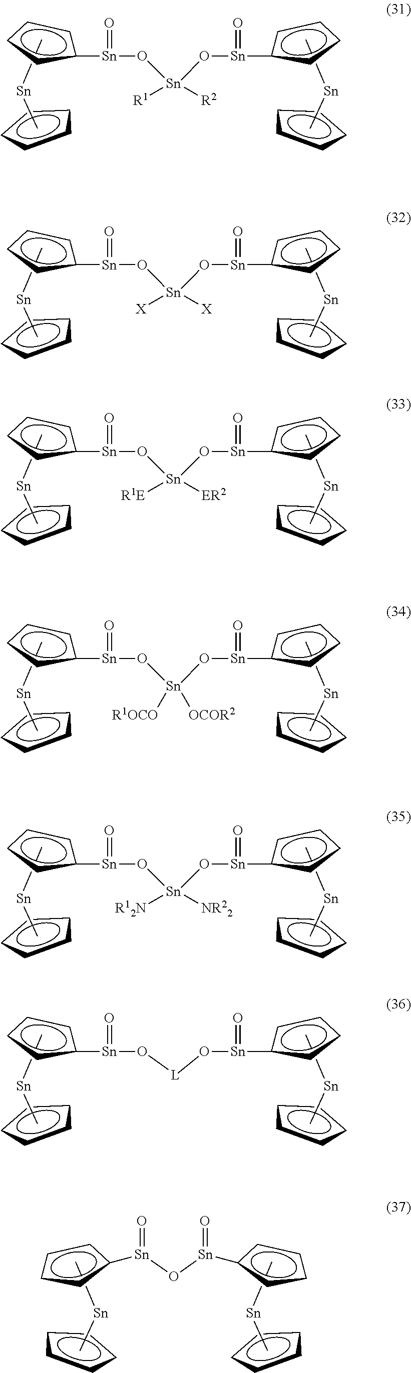 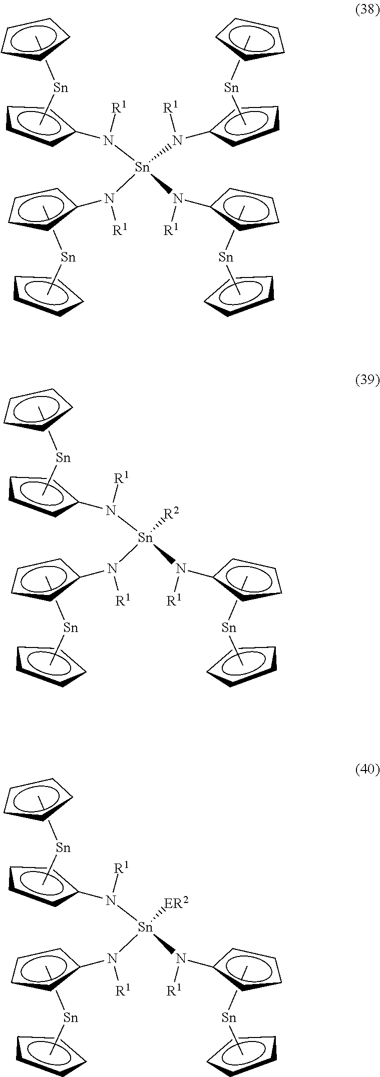 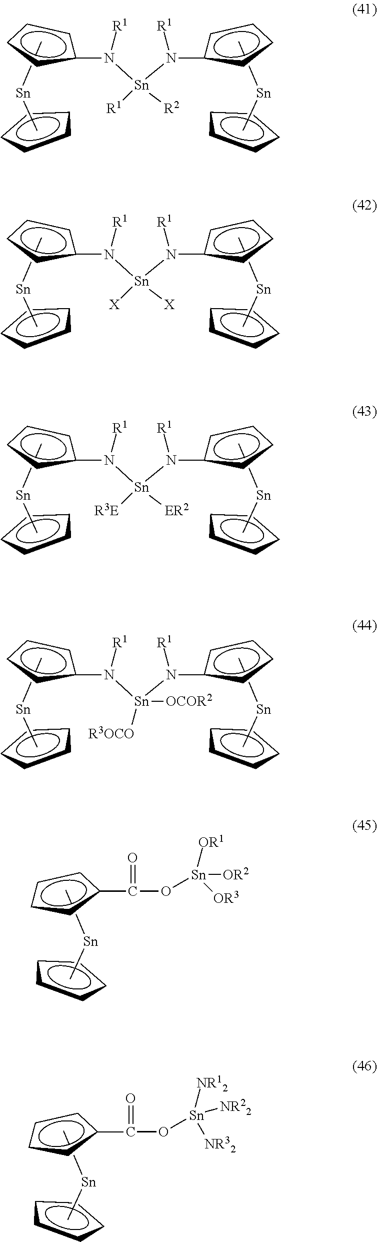 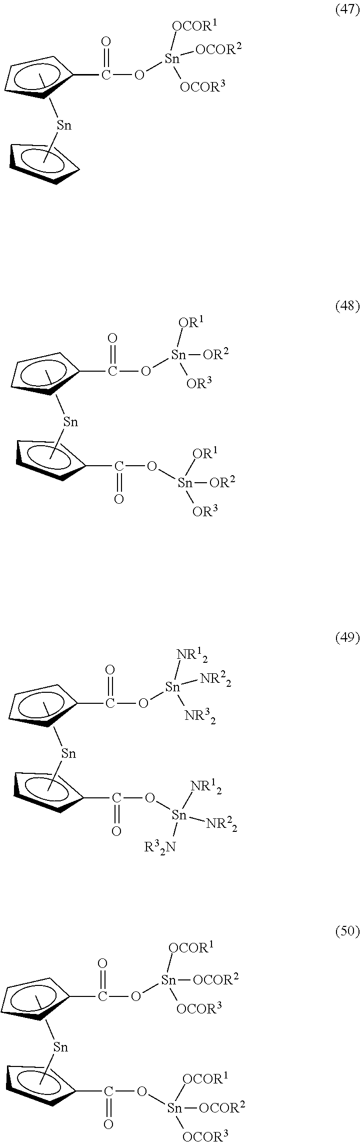
wherein R¹, R², R³ are each independently H, a substituted or unsubstituted alkyl, alkenyl, alkynyl, cycloalkyl, cycloalkenyl, or cycloalkenyl group with 1 to 20 carbon atoms, or a substituted or unsubstituted aryl group with 6-20 carbon atoms, E=O, S, Se, or Te, X=F, Cl, Br, or I, L is a substituted or unsubstituted alkyl, alkylene, alkenyl, alkynyl, cycloalkyl, or cycloalkenyl group with 1 to 20 carbon atoms, or a substituted or unsaturated aryl group with 6-20 carbon atoms.

2. The organotin compound as photoresist of claim 1, wherein stannocenyl includes bis(cyclopentadienyl)tin, or substituted bis(cyclopentadienyl)tin group, wherein cyclopentadienyl comprises cyclopentadienyl C₅H₅, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

3. The organotin compound as photoresist of claim 1, wherein R¹, R², R³ are each independently an alkyl, alkenyl, or aryl group, E=O, S, Se, or Te, X=Cl, L=alkylene.

4. The organotin compound as photoresist of claim 1, wherein the actinic radiation is extreme ultraviolet radiation, deep ultraviolet radiation, e-beam radiation, X-ray radiation, or ion-beam radiation.

5. An organotin photoresist composition for photolithography patterning, comprising:
a (stannocenyl)tin compound, a solvent, and an additive;
wherein (stannocenyl)tin compound is one or more selected from the following: 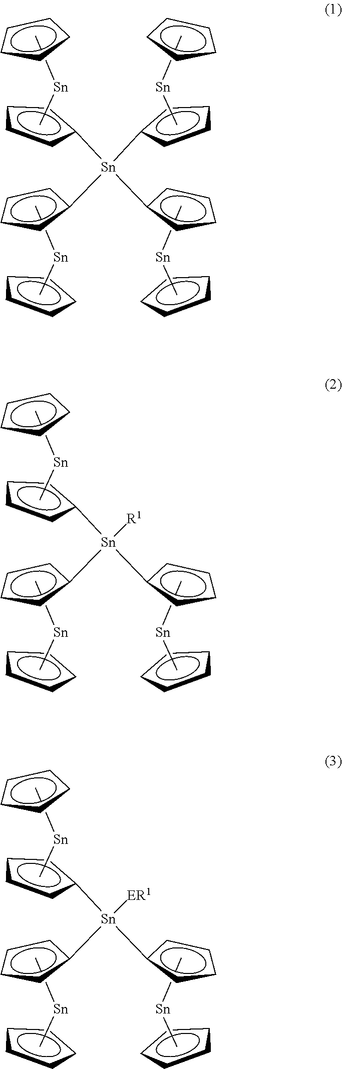 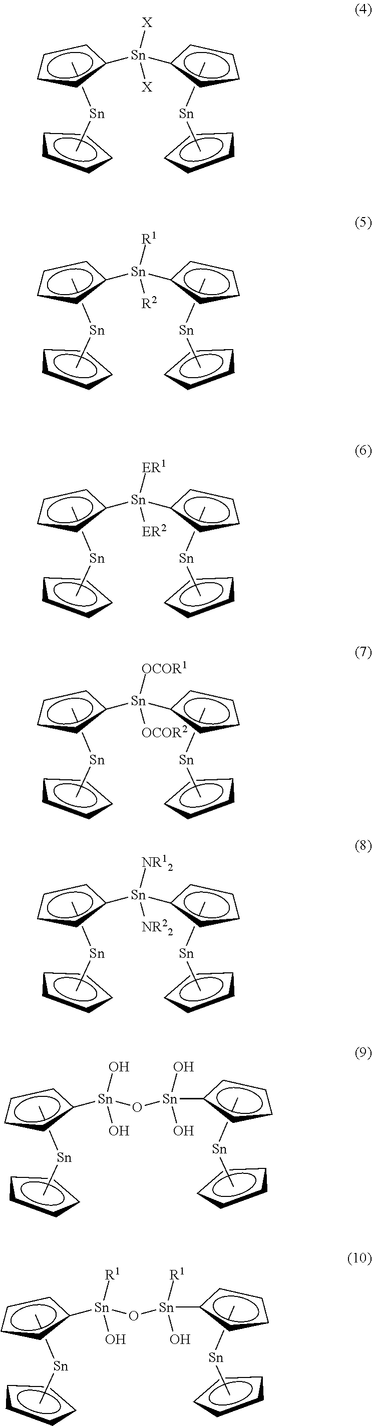 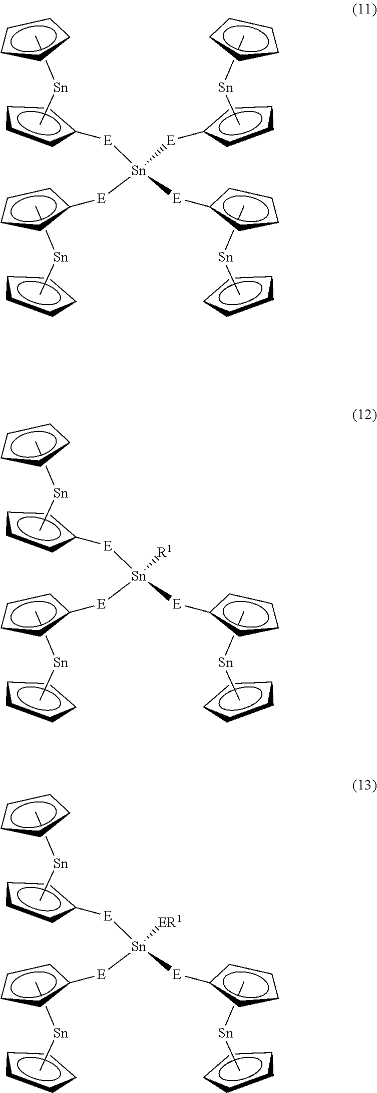 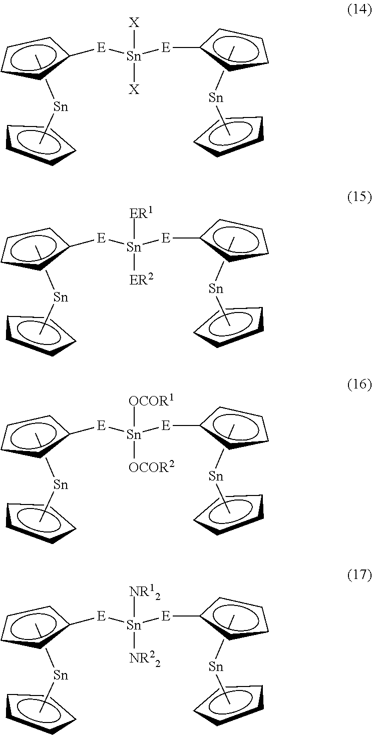 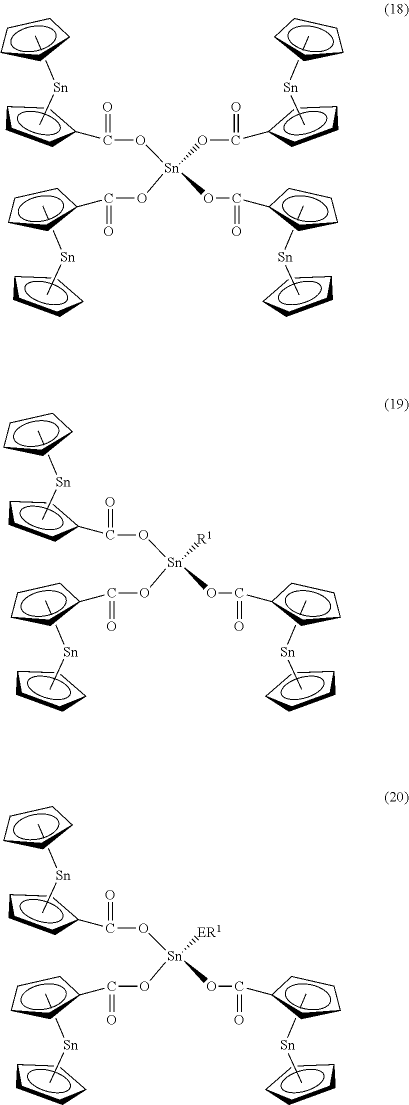 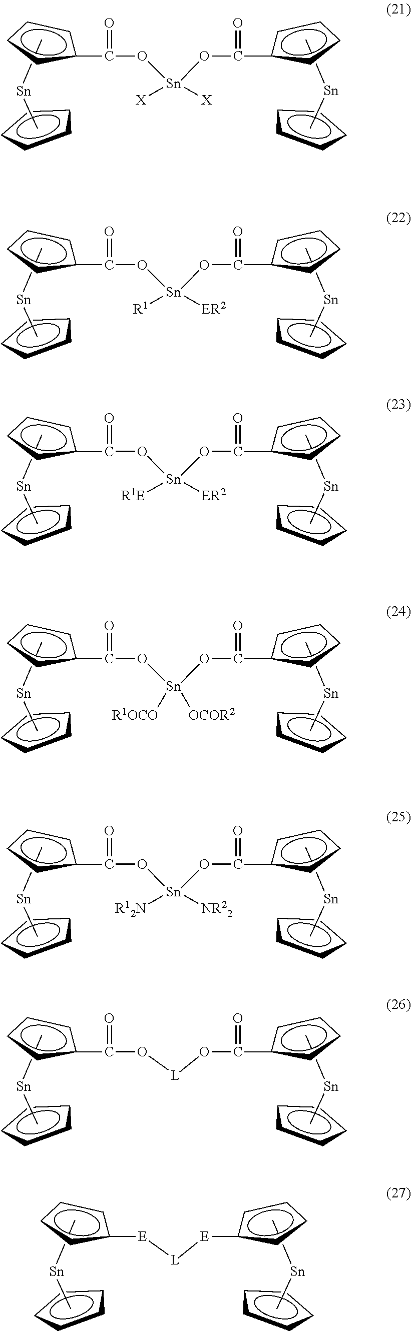 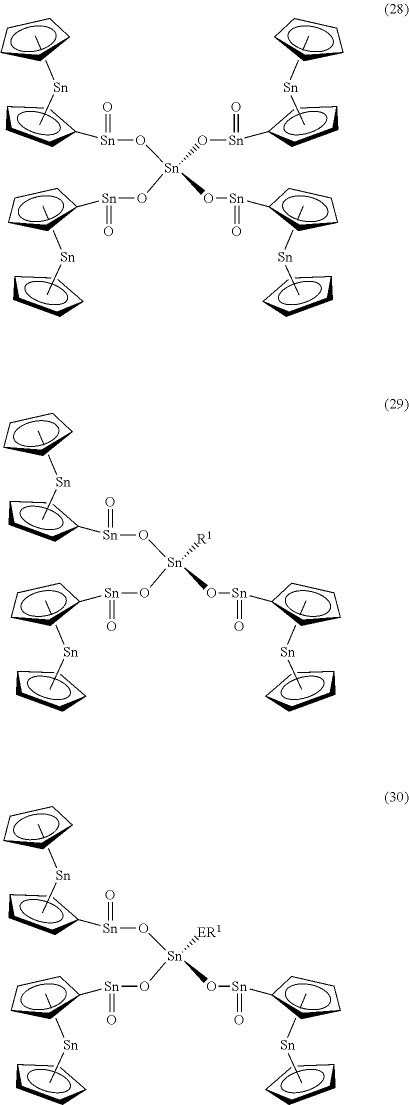 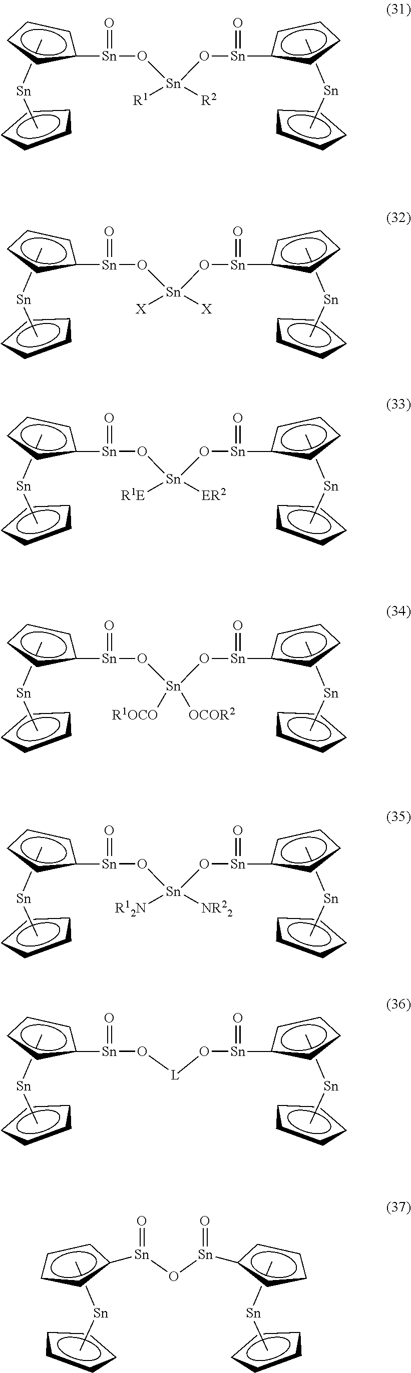 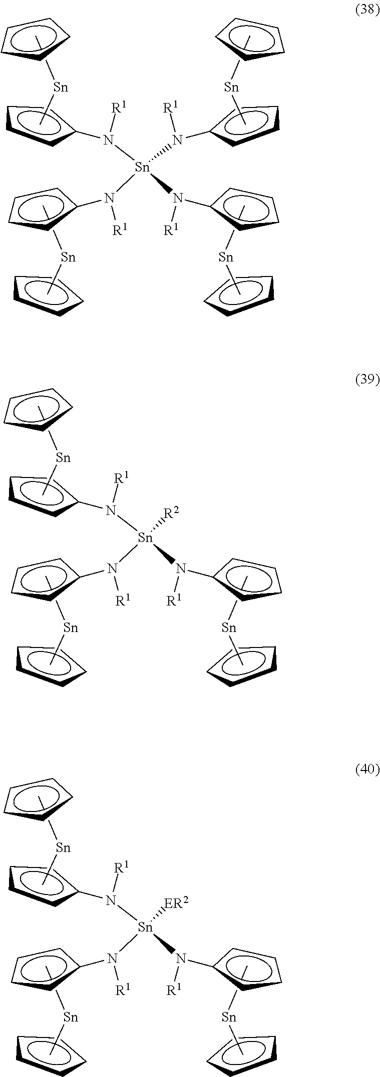 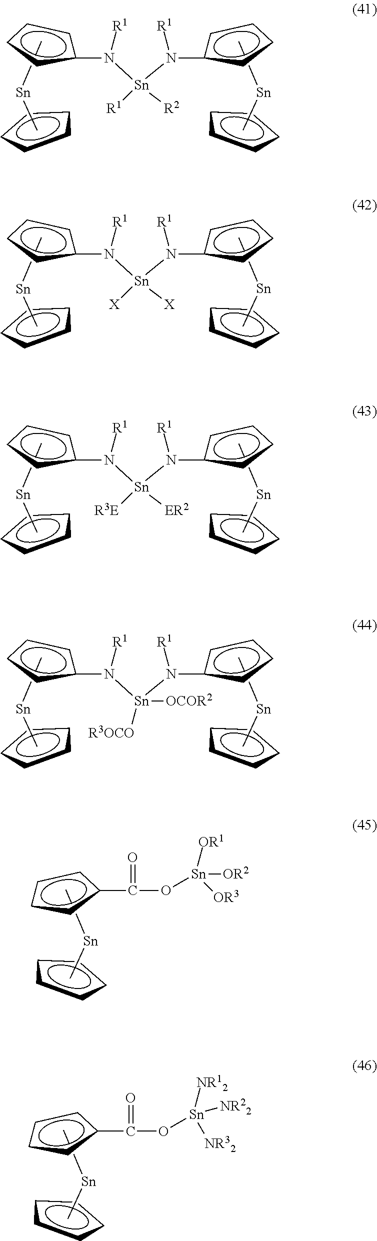 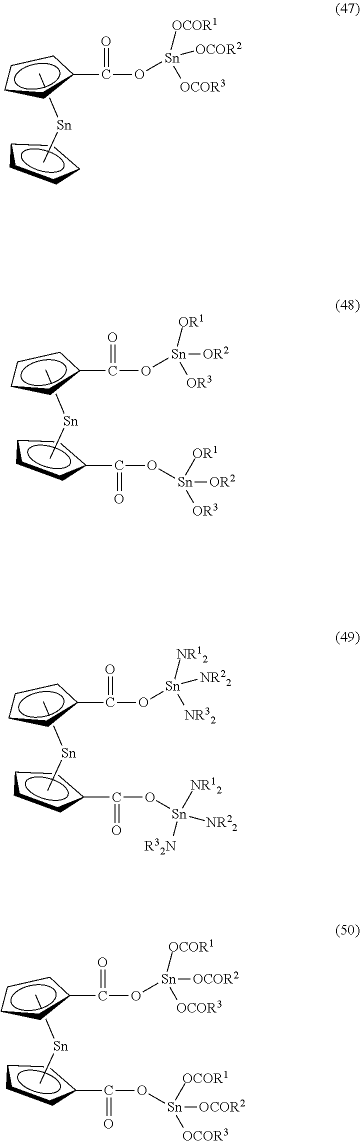
wherein R¹, R², R³ are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te, X=F, Cl, Br, or I; L is a substituted or unsubstituted alkyl, alkylene, alkenyl, alkynyl, cycloalkyl, or cycloalkenyl group with 1 to 20 carbon atoms, or a substituted or unsaturated aryl group with 6-20 carbon atoms.

6. The organotin photoresist composition of claim 5, wherein stannocenyl includes bis(cyclopentadienyl)tin, or substituted bis(cyclopentadienyl)tin, wherein cyclopentadienyl group includes cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms; or a substituted or unsubstituted aryl group with 6-20 carbon atoms, or an amino, cyano, ether, ester, halide, nitro, silyl, thiol, or carbonyl group.

7. The organotin photoresist composition of claim 5, wherein cycloalkenyl group comprises a substituted or unsubstituted C4 to C8 cyclic aliphatic unsaturated organic groups including at least one double bond.

8. The organotin photoresist composition of claim 5, wherein the additive for stabilizing (stannocenyl)tin compound photoresist comprises organic thiol, organic alcohol, organic amine, organic amide, organic carboxylic acid, organic phosphine, organic phosphine oxide, or organic phosphonic acid.

9. The organotin photoresist composition of claim 5, wherein the additive includes 1-dodecanethiol, 2-dodecanethiol, 1,12-dodecanedithiol, 1-dodecanol, 1-octanol, 1-hexadecanol, 1-heptadecyloctadecylamine, decylamine, dodecylamine, decanamide, docosanamide, dodecanamide, oleic acid, citric acid, decanoic acid, hexadecanedioic acid, trioctylphosphine, tributylphosphine, trioctylphospine oxide, hexylphosphonic acid, octadecylphosphonic acid, 11-undecenyl phosphonic acid, or combinations thereof.

10. The organotin photoresist composition of claim 5, wherein the (stannocenyl)tin compounds may be used as precursors for photolithography patterning.

11. The organotin photoresist composition of claim 5, wherein photolithography patterning includes extreme ultraviolet radiation, deep ultraviolet radiation, e-beam radiation, X-ray radiation, or ion-beam radiation.

12. The organotin photoresist composition of claim 6, wherein R is H, an alkyl, or aryl group.

13. The organotin photoresist composition of claim 5, wherein R¹, R², R³, are each independently an alkyl, alkenyl, or cycloalkenyl group.

14. The organotin photoresist composition of claim 5, wherein L is an alkylene.

15. The organotin photoresist composition of claim 6, wherein R is H, a methyl, ethyl, propyl, n-butyl, or t-butyl, or phenyl group.

16. The organotin photoresist composition of claim 5, wherein R¹, R², R³ are each independently a methyl, ethyl, propyl, n-butyl, t-butyl, or cyclopentadienyl group.

17. The organotin photoresist composition of claim 5, wherein E=O, or S.

18. The organotin photoresist composition of claim 5, wherein X=Cl.

19. An organotin compound bearing stannocenyl group is represented by chemical formula as below: 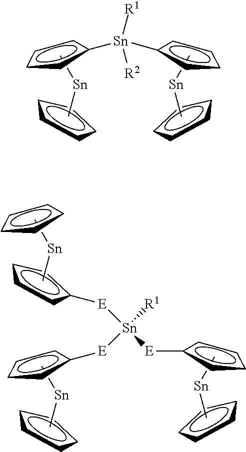
wherein R¹, R² are each independently substituted and unsubstituted alkyl, alkenyl, alkynyl, cycloalkyl, or cycloalkenyl group with 1 to 20 carbon atoms, or substituted and unsubstituted aryl group with 6-20 carbon atoms, E is O, S, Se, or Te.

20. The organotin compound of claim 19, wherein stannocenyl is bis(cyclopentadienyl)tin, or substituted bis(cyclopentadienyl)tin, wherein cyclopentadienyl comprising cyclopentadienyl C₅H₅ group, or substituted cyclopentadienyl C₅H₃R, C₅H₂R₂, C₅HR₃, or C₅R₄ group with hapticity of η¹, η², η³, η⁴ or η⁵ of isomers, wherein R is H, a substituted and unsubstituted alkyl, alkenyl, alkynyl, or cycloalkyl group with 1 to 20 carbon atoms, or a substituted and unsubstituted aryl group with 6-20 carbon atoms, or an amino, cyano, ether, ester, halide, nitro, silyl, thiol, or carbonyl group.
